(19) United States
(12) Patent Application Publication
(10) Pub. No.: US 2012/0249142 A1
(43) Pub. Date: Oct. 4, 2012

(54) LOCAL COIL

(76) Inventors: Stephan Biber, Erlangen (DE); Yvonne Candidus, Tuchenbach (DE); Daniel Driemel, Oederan (DE)

(21) Appl. No.: 13/434,616

(22) Filed: Mar. 29, 2012

(30) Foreign Application Priority Data
Mar. 31, 2011 (DE) 10 2011 006 569.5

(51) Int. Cl. G01R 33/381; G01R 33/56

(52) U.S. Cl. 324/309; 324/322

(57) ABSTRACT

A local coil for a magnetic resonance tomography system includes a housing with a recess for an object under examination. The local coil also includes a radio-frequency receive antenna system and one or more shim elements for homogenization of a static basic magnetic field of the magnetic resonance tomography system.

This application claims the benefit of DE 10 2011 006 569.5, filed on Mar. 31, 2011.

### BACKGROUND

The present embodiments relate to a local coil for magnetic resonance tomography.

In a magnetic resonance device, the body to be examined may be subjected to a static basic magnetic field that is as homogeneous as possible (e.g., also referred to as the B₀ field), with the aid of a basic magnetic field system. In addition, a magnetic field gradient is applied with the aid of a gradient system. The radio-frequency magnetic resonance excitation signals (RF signals) with defined field strengths are then transmitted by suitable antennas. The magnetic flux density of the RF signals may be designated B₁. The pulse-shaped radio frequency field may thus also be abbreviated to the B₁ field. By the RF pulses, the nuclear spin of specific atoms excited resonantly by the high frequency field are flipped by a defined flip angle in relation to the magnetic field lines of the basic magnetic field (B₀ field). On relaxation of the nuclear spin, radio frequency signals (e.g., magnetic resonance signals) are emitted. The magnetic resonance signals are received by suitable radio-frequency antennas (e.g., RX antennas) and then further processed. From the raw data thus acquired, the desired magnetic resonance image data (MR image data) may be reconstructed. Local encoding is performed by switching suitable magnetic field gradients in the different space directions at precisely defined times (e.g., during the sending out of the RF signals and/or during the reception of the magnetic resonance signals). The high-frequency signals for nuclear spin magnetization may be undertaken with a bodycoil built into the magnetic resonance tomograph. A typical structure for this is a birdcage antenna consisting of a number of transmit rods. The transmit rods are disposed, running in parallel to the longitudinal axis, around a patient space of the tomograph, in which an object under examination (e.g., a patient) is located during the examination. On end face sides, the antenna rods are respectively connected to each other in the shape of a ring.

Local coils (e.g., coils) may be used to receive the magnetic resonance signals with a high signal-to-noise ratio (SNR). These are antenna systems that are attached in the immediate vicinity on (anterior) or below (posterior) the patient. The magnetic resonance signals are received in the individual antennas of the local coil, and the magnetic resonance signals are converted into a voltage that is amplified with a low noise preamplifier (LNA, Preamp). The amplified signals are passed on via a cable connection to receive electronics. To improve the signal-to-noise ratio (e.g., with high-resolution images), high field systems are employed. The system operates, for example, with the basic magnetic field B₀ of 1.5 to 12 tesla and more.

Of importance in many magnetic resonance applications (e.g., clinical MRT) is the homogeneity of the B₀ basic magnetic field. Thus, with variations in the homogeneity, for example, artifacts or distortions may arise, or specific applications such as fat saturation methods (“FatSat”) no longer function. Fat saturation is a technique, in which a frequency shift of the protons bound into fat is used in order to filter out the signals of fatty tissue at the fat frequency by a strong send pulse (e.g., a saturation pulse). Since the difference between the proton frequency in water and the frequency in fat is very small (e.g., only a few ppm of the basic magnetic field), this technique is heavily dependent on the spatial homogeneity of the basic magnetic field. Suitably homogeneous basic magnetic fields with a frequency difference of more than a maximum of 0.5 ppm are currently achieved over volumes of around 30×30×30 cm³.

A distortion of the B₀ basic field may also occur in different body regions. The reason for this is a spatially greatly inhomogeneous distribution of the susceptibility of the body tissue. The susceptibility (e.g., specified as the magnetic volume susceptibility χ_{V}) is a measure for the magnetizability of material in an external magnetic field and has a simple relationship to the magnetic permeability μᵣ (e.g., μᵣ=χ_{V}+1).

The distortions arising as a result of different susceptibilities of the body tissue may be corrected via shim coils permanently built into the MR system. The number of different shim coils in magnetic resonance tomographs, the arrangement of the shim coils and control of the shim coils, however, only allow a limited number of degrees of freedom in order to compensate for a B₀ inhomogeneity of the mostly superconducting basic field magnet system by shim currents in conventional bodycoils. The number of the degrees of freedom is not sufficient with many conventional MR systems to sufficiently compensate for an inhomogeneity of the B₀ field in all areas of the body. Problems occur in, for example, the area of the extremities and the cervical spine (HWS) or the nape of the neck. In these areas (e.g., at the transition from the thorax to the neck or head), a greater susceptibility jump may arise between the individual tissue types. Bones, cartilage or fat deposits are also counted as tissue within the present embodiments.

As an alternative to the shim coils built into the MR system (e.g., if the shim arrangements (degrees of freedom) are not sufficient), the inhomogeneity in the B₀ field is compensated for by gel pads that are placed, for example, in the area of the nape of the neck or in the area of an inhomogeneity of the B₀ between the local coil and the object under examination. The gel pads have a residual susceptibility that is designed to counteract the B₀ distortions so that a more homogeneous basic magnetic field B₀ arises. The disadvantage of this basic field correction method is that the gel pads are difficult to handle, reproducibility is low, requirements for the pads in the coil are high, and there is a low acceptance among users and patients. For example, the tolerance requirement is a disadvantage with coils fitted very closely on the body, since either larger coils are to be used, leading to a greater SNR disadvantage, or the number of patients for whom the coil is tailored is reduced. Different coils may be kept in stock to allow reaction to different body situations and the different sizes of the pad.

### SUMMARY AND DESCRIPTION

The present embodiments may obviate one or more of the drawbacks or limitations in the related art. For example, an improved alternative to the previous local coils and methods for creating magnetic resonance images with the aid of a homogenization of the static basic magnetic field of a magnetic resonance tomography system is provided.

A local coil for a magnetic resonance tomography system includes a housing with a recess for an object under examination. The local coil also includes a radio-frequency receive antenna system and one or more shim elements for homogenization of a static basic magnetic field of the magnetic resonance tomography system. The static basic magnetic field may be the static basic magnetic field (B₀ field), which is as homogeneous as possible, applied from outside by a magnetic coil. The static basic magnetic field, depending on the device, may have a field strength of between 1.5 and 7 tesla and is flipped in relation to the atoms excited by the B₁ field.

Local coils with recesses for different applications (e.g., a head coil for the head and cervical spine area or coils for extremities such as for the knee, ankle, wrist, elbow or the shoulder) are widely known to the person skilled in the art. For all these local coils and, for example, for coils at an edge of a field of view (FoV), integrating shim elements for homogenization of a static basic magnetic field into the local coil is advantageous, since large susceptibility differences of the tissue and therefore also a large inhomogeneity of the B₀ field may arise. The reproducibility may be improved, and the shim elements do not occupy any space actually needed for the object under examination in the recess of the coil. Thus, the local coils are more readily accepted both by the users and also by the patients than the previous solutions such as usual gel pads, for example.

The integration of the shim elements into the local coil, also makes it unnecessary to enlarge the local coils, since the radio frequency antennas do not have to be spaced further from the object under examination. Thus, a good signal-to-noise ratio with an advantageous size of the local coil may also be achieved.

In one embodiment of a method for creating magnetic resonance images of an object under examination with a local coil for a magnetic resonance system for homogenization of a static basic magnetic field of the magnetic resonance tomography system, one or more shim elements are arranged integrated into or onto a housing of the local coil.

Through the use of the local coil with one or more shim elements for homogenization of the static basic magnetic field of a magnetic resonance tomography system, the disadvantages of conventional methods may be overcome (e.g., with better reproducibility, greater acceptance of the coils, a better signal-to-noise ratio).

At least one of the shim elements is arranged in the housing. Arranged in the housing may be that the shim element may be arranged for homogenization of the B₀ field within the housing of the local coil (e.g., inside the housing or also at an edge of the housing). In one embodiment, the shim elements are arranged between the object under examination and the radio-frequency receive antenna. Viewed from the object under examination outwards, the shim elements may also lie behind the antenna. An integration into the housing part surrounding the antenna (e.g., into a recess provided for this purpose in the housing wall) is possible so that the shim elements may also be in direct contact with the object under examination.

In one embodiment, the coil housing is embodied at least in some areas as a shim element. For example, the coil housing may, at least in an area with suspected field inhomogeneity but also overall, be constructed from a material with matched susceptibility, as will be further explained below.

According to another embodiment, the shim elements may be arranged at a distance of between 3 and 80 mm (e.g., between 5 and 50 mm) from an object under examination to be moved into the local coil (e.g., to the local coil surface, with which the object under examination has contact during the measurement). It may thus be advantageous for the shim elements to be arranged as close as possible to the area of the object under examination, in which an inhomogeneity of the B₀ field occurs.

In another embodiment of the local coil, at least one of the shim elements (e.g., a plurality of shim elements or all shim elements) is constructed from materials with suitable susceptibility. It is advantageous for the shim element and the tissue of the patient to be examined to exhibit similar susceptibility values. Materials with a magnetic susceptibility similar to that of water are suitable for the shim elements, since the tissue of a patient is predominantly made up of water. In one embodiment, the magnetic susceptibility χ_{V} ranges from around −5×10⁻⁶ to −15×10⁻⁶ (in SI units) (e.g., more than −7×10⁻⁶ or −8×10⁻⁶ and less than −12×10⁻⁶ or −11×10⁻⁶, since water at 20° C. has a magnetic volume susceptibility χ_{V} of −9.0×10⁻⁶).

Examples of such materials with suitable susceptibility are water-retaining gels or foams (e.g., soft plastic foams) filled with slightly diamagnetic materials (e.g., graphite, graphene or carbon nanotubes). The slightly diamagnetic materials may, however, also be distributed in a solid element body (e.g., made from a plastic material). The shim elements are not manufactured from a material that may be too greatly magnetic or too greatly conductive (e.g., simple bulk carbon). In one embodiment, the materials are incorporated as fine powder into a material matrix of another material (e.g., a plastic), and the materials have the right diamagnetic properties. This may depend on the microstructure of the materials. For example, bulk carbon has a different diamagnetism than soot.

Suitable materials for use in soft foams or hard plastics are, for example, different carbon modifications with slightly diamagnetic properties such as, for example, graphite, graphene or carbon nanotubes. Further information about this may be found in the article entitled “Pyrolytic graphite foam: a passive magnetic susceptibility matching material,” in J. Magn. Reson. Imaging 32(3), September 2010: pp. 684-91.

These materials are suitable, for example, for use in pad form, in which the gel or the foam is enclosed in an envelope. The pads are integrated into the local coil in accordance with the present embodiments. As an alternative, foams and alternative materials may also be put into a corresponding external shape and built-in directly without separate shrouding into the housing of the local coil.

If a gel (e.g., a water-retaining gel or a fluid) is used as the material for the shim element, the shim element may still retain its external form during the magnetic resonance measurement, so that the desired homogenization effect is obtained evenly as a result of the shape retention. The gel is therefore advantageous for preserving the shape to provide the shim element with a rigid envelope. Any MR-mute, suitably diffusion dense material compatible with an MR system is suitable for the semiconductor envelope, as is, for example, also used already for the housing of the local coil.

As an alternative to a gel filling of a pad, a filling without gel may use a compartmented envelope, for example, with webs inside in order to improve the shape retention of the shim element.

All materials that are toxologically non-controversial and form a gel with the desired consistency and susceptibility may be used as gel agents. For example, sodium poly-acrylate distributed in the form of a dry wetted sodium poly-acrylate powder having a particle size of maximum 0.5 mm (e.g., below around 0.2 mm) may be used. Larger particle sizes may lead to the final gel being less homogeneous. The smaller the particle size the more homogeneous the resulting gel may be. Agarose, polysaccaride, polyacrylic acids, polyvinylpyrrolidone, polyvinylalcohol, polyacrylamide, and modified starches or cellulose may also be used as gel agents or to set a high viscosity, or a thixotropic or structure-viscose flow behavior.

The underlying acrylate monomers may be substituted (e.g., by alkyl, alkoxy or hydroxyalkyl groups). Copolymers with, if necessary, substituted acrylamide may also be used.

The gelling agent may be present in a concentration of 0.1-10% by weight (e.g., of approximately 0.5-5% by weight).

The gel may also contain a compound of conservation that may be present in a proportion of more than 20% by weight (e.g., of 25% by weight). Examples of the compound of conservation are 1,2 propanediol, ethanol or 2-propanol.

A commercially available ultrasound contact gel based on water may also be used as the basic compound for the shim element that already contains gelling agents and, if necessary, the compound of conservation.

The use of shim elements (e.g., of gel pads), foam elements or elements from plastic is advantageous in the local coil, because through the greatly localized influence of the shim elements, the B₀ inhomogeneity (e.g., the inhomogeneity of the static basic magnetic field B₀) may be compensated. The B₀ inhomogeneity would otherwise need a high shim order or a high space requirement in the coil (e.g., through gel pads in the recess for the patient). In one embodiment, a number of shim elements may be integrated into a local coil of the present embodiments. The shim elements may be arranged directly at the location of the local B₀ inhomogeneity within the local coil.

In one embodiment of the local coil, the recess for the object under examination is therefore at least adapted to a part of a part of the body such as, for example, the head, the knee, the foot, the elbow, the shoulder, or a combination thereof. Both the high-frequency receive antennas and the shim elements may thus be able to be integrated at as small a distance as possible from the object under examination and where possible, with an arrangement specifically designed for the part of the body to be examined in the housing of the local coil. This enables expected (e.g., the usual susceptibility) jumps occurring in the individual parts of the body to be taken into account precisely so that the overall layout is simplified. Thus, it may be sufficient, for example, to provide individual fixed shim elements that create, for the corresponding part of the body, an optimized homogeneous basic magnetic field integrated into a housing, as soon as an object under examination is located in the recess.

The local coil of the present embodiments (e.g., involving a head coil), for which the recess matches the head and/or nape of the neck area and at least one shim element in the housing are embodied in the area of the nape of the neck (e.g., at the transition from thorax to head). For example, the coil housing may also be embodied as a shim element in the nape of the neck area by the housing there being made from a material with suitable susceptibility. Since in the cervical spine area, because of the different tissues structure and the susceptibility differences associated therewith, a strong inhomogeneity of the B₀ frequently arises, the local coils of the present embodiments achieve marked improvements compared to previous systems. For example, an improved reproducibility and improved signal-to-noise ratio or a fat saturation may be achieved. No gel pads are needed in the area the patient (e.g., in the recess provided for the head and/or nape of the neck area).

### BRIEF DESCRIPTION OF THE DRAWINGS

FIG. 1 shows one embodiment of a local coil.

### DETAILED DESCRIPTION OF THE DRAWINGS

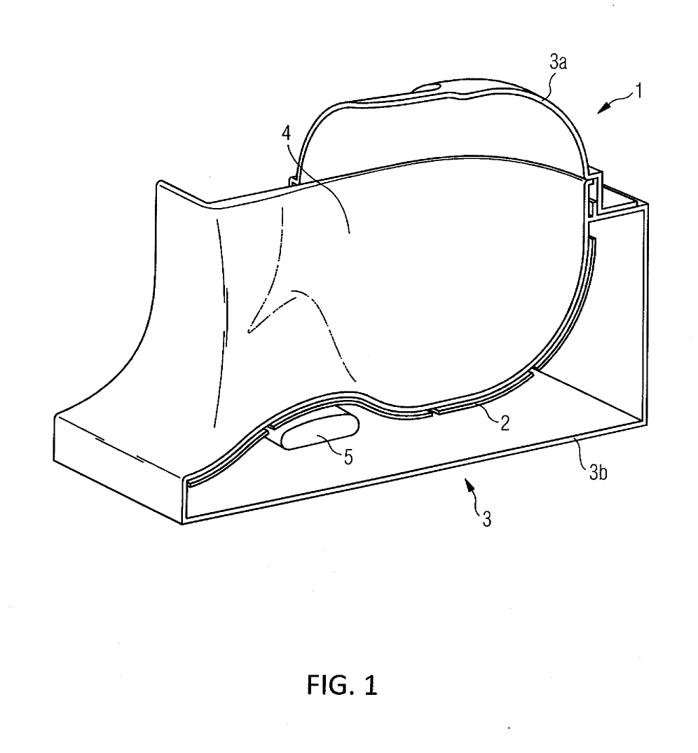

FIG. 1 shows one embodiment of a local coil 1. The local coil 1 is a head coil 1 that is adapted for magnetic resonance (MR) examination of the entire head area including the cervical spine and the nape of the neck area. The head coil 1 includes a radio-frequency receive antenna system 2 having a plurality of radio-frequency receive antennas, a housing 3 with a recess 4 for an object under examination, and a shim element 5.

The housing 3 and the recess embodied therein are embodied for the head and nape of the neck area of a patient. The patient may lay his head from the shoulders into the head coil 1. The patient is fixed with an upper housing part 3a that is embodied removably from a lower housing part 3b, so that the patient may move his head as little as possible or not as all during the measurement. The upper housing part 3a extends around the chin and is provided with openings (not shown in the figure) for the eyes, nose and mouth. In one embodiment, radio-frequency antennas or shim elements, which are not depicted in the embodiment shown in FIG. 1, may also be provided therein.

A number of radio-frequency receive antennas (e.g., RX antennas; four separate antenna elements in the form of conductor loops coupled together) are arranged below the recess 4 in an area of the back of the patient's head and in an area of the neck and shoulders over the entire area from shoulder to back of the head. The RX antennas receive magnetic resonance signals emitted by the relaxation of the nuclear spin. The magnetic resonance signals are then forwarded in the usual manner for further processing to a controller of the MR system. From the “raw data” acquired with the RX antennas, desired magnetic resonance image data (e.g., MR image data) may be reconstructed.

Below the RX antennas of the radio-frequency receive antenna system 2 (e.g., on a side of the RX antennas facing away from the patient, in the area of the neck, between shoulder and head), a shim element 5 is provided in the form of a foam body. The foam body is embodied in a stable shape from an MR- mute and MR-compatible foam material and contains finely-distributed graphite powder for setting a suitable susceptibility. The susceptibility of the shim elements used approximately corresponds to that of water so that the B₀ inhomogeneity usually occurring in the nape of the neck area may be compensated. The shim 5 is arranged directly at the site of the local B₀ inhomogeneity (e.g., below the nape of the neck area) and varies spatially in strength in order to adapt to different field lines. For example, the shim element 5 may be slightly thinner at the edge (e.g., in the area towards the thorax, towards the head, or to a side of the cervical spine), so that an optimization of the homogeneity of the B₀ is achieved.

The local coil and the method of the present embodiments may be modified in a wide variety of ways by a person skilled in the art without departing from the invention. Although the present embodiments have been described using magnetic resonances in the medical field as examples, the possible uses of the invention are not restricted to this area. The invention may also be used in scientifically and/or industrially-used magnetic resonance devices. The use of the indefinite article “a” or “an” does not exclude the features involved being present a number of times.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A local coil for a magnetic resonance tomography system, the local coil comprising:
a housing comprising a recess for an object to be examined;
a radio-frequency receive antenna system; and
one or more shim elements for homogenization of a static basic magnetic field of the magnetic resonance tomography system.

2. The local coil as claimed in claim 1, wherein at least one of the one or more shim elements are arranged in the housing.

3. The local coil as claimed in claim 1, wherein the one or more shim elements are arranged at a distance of 3 to 80 mm from the object to be examined to be accommodated in the recess of the housing.

4. The local coil as claimed in claim 1, wherein at least one of the one or more shim elements are constructed from materials with a magnetic susceptibility χ_{V} ranging from −5×10⁻⁶ to −15×10⁻⁶ in SI units.

5. The local coil as claimed in claim 4, wherein the materials include a water-retaining gel, a foam, or plastic containing a diamagnetic material.

6. The local coil as claimed in claim 5, wherein the diamagnetic material is graphite, graphene or carbon nanotubes.

7. The local coil as claimed in claim 1, wherein the coil housing is configured, at least in some areas, as a shim element of the one or more shim elements.

8. The local coil as claimed in claim 1, wherein the recess is adapted at least to a part of a part of the body of the object to be examined.

9. The local coil as claimed in claim 8, wherein the local coil is a head coil, in which the recess is adapted to the head, nape, or head and nape of the neck area, and
wherein at least one shim element of the one or more shim elements is in the housing in the area of the nape of the neck.

10. The local coil as claimed in claim 2, wherein the one or more shim elements are arranged at a distance of 3 to 80 mm from the object to be examined to be accommodated in the recess of the housing.

11. The local coil as claimed in claim 2, wherein at least one of the one or more shim elements are constructed from materials with a magnetic susceptibility χ_{V} ranging from −5×10⁻⁶ to −15×10⁻⁶ in SI units.

12. The local coil as claimed in claim 3, wherein at least one of the one or more shim elements are constructed from materials with a magnetic susceptibility χ_{V} ranging from −5×10⁻⁶ to −15×10⁻⁶ in SI units.

13. The local coil as claimed in claim 2, wherein the coil housing is configured, at least in some areas, as a shim element of the one or more shim elements.

14. The local coil as claimed in claim 3, wherein the coil housing is configured, at least in some areas, as a shim element of the one or more shim elements.

15. The local coil as claimed in claim 6, wherein the coil housing is configured, at least in some areas, as a shim element of the one or more shim elements.

16. The local coil as claimed in claim 2, wherein the recess is adapted at least to a part of a part of the body of the object to be examined.

17. The local coil as claimed in claim 3, wherein the recess is adapted at least to a part of a part of the body of the object to be examined.

18. The local coil as claimed in claim 6, wherein the recess is adapted at least to a part of a part of the body of the object to be examined.

19. A method for creating magnetic resonance images of an object under examination with a local coil for a magnetic resonance tomography system, the method comprising:
arranging one or more shim elements for homogenization of a static basic magnetic field of the magnetic resonance tomography system in or on a housing of the local coil.

20. A method comprising:
placing one or more shim elements in a housing of a local coil;
placing an object to be examined in a recess of the housing;
homogenizing a static basis magnetic field of a magnetic resonance tomography system with the one or more shim elements; and
receiving radio frequency signals with a radio-frequency receive antenna of the local coil, the radio frequency signals responsive to the homogenizing.
